(19) United States
(12) Patent Application Publication
(10) Pub. No.: US 2022/0269162 A1
(43) Pub. Date: Aug. 25, 2022

(54) OPTICAL ELEMENT FOR REFLECTING EUV RADIATION, EUV LITHOGRAPHY SYSTEM AND METHOD FOR SEALING A GAP

(71) Applicant: Carl Zeiss SMT GmbH, Oberkochen (DE)

(72) Inventor: Anastasia GONCHAR, Ulm (DE)

(21) Appl. No.: 17/679,720

(22) Filed: Feb. 24, 2022

Related U.S. Application Data
(63) Continuation of application No. PCT/EP2020/072046, filed on Aug. 5, 2020.

(30) Foreign Application Priority Data
Aug. 26, 2019 (DE) 10 2019 212 736.3

(51) Int. Cl. G03F 1/24; G03F 1/48

(52) U.S. Cl. CPC G03F 1/24; G03F 1/48; G03F 7/70033

(57) ABSTRACT

An optical element (1) for reflecting EUV radiation (4) includes: a substrate (2); a coating (3) applied to the substrate (2), which coating reflects the EUV radiation (4); a top layer (5) protecting the reflective coating (3), which top layer is applied to the reflective coating (3); and an intermediate layer (6) having at least one reactive material (7) which, together with an activating gas (O2) penetrating through a gap (5a) in the top layer 95), forms at least one reaction product (8) sealing the gap (5a). A related EUV lithography system has at least one such reflective optical element (1), and a related method for sealing a gap (5a) in the top layer (5) of such an optical element (1) are also disclosed.

### CROSS-REFERENCE TO RELATED APPLICATION

This is a Continuation of International Application PCT/EP2020/072046, which has an international filing date of Aug. 5, 2020, and the disclosure of which is incorporated in its entirety into the present Continuation by reference. This Continuation also claims foreign priority under 35 U.S.C. § 119(a)-(d) to and also incorporates by reference, in its entirety, German Patent Application DE 10 2019 212 736.3 filed on Aug. 26, 2019.

### FIELD OF THE INVENTION

The invention relates to an optical element for reflecting EUV radiation, comprising: a substrate, a reflective coating applied to the substrate, said coating reflecting the EUV radiation, a capping layer applied to the reflective coating for protecting the reflective coating, and an intermediate layer arranged between the reflective coating and the capping layer. The invention also relates to an EUV lithography system comprising at least one such reflective optical element, and to a method for sealing a gap in the capping layer of such an optical element.

### BACKGROUND

For the purposes of this application, an EUV lithography system is understood as meaning an optical system or an optical arrangement for EUV lithography, i.e. an optical system that can be used in the field of EUV lithography. Apart from an EUV lithography apparatus used for producing semiconductor components, the optical system can be for example an inspection system for the inspection of a photomask (hereinafter also referred to as a reticle) used in an EUV lithography apparatus, for the inspection of a semiconductor substrate to be structured (hereinafter also referred to as a wafer), or a metrology system used for measuring an EUV lithography apparatus or parts thereof, for example for measuring a projection system.

EUV radiation (extreme ultraviolet radiation) is understood to mean radiation in a wavelength range of between approximately 5 nm and approximately 30 nm, for example at 13.5 nm. Since EUV radiation is greatly absorbed by most known materials, the EUV radiation is typically guided through the EUV lithography system with the aid of reflective optical elements.

A reflective optical element embodied as described above has been disclosed by EP 1 402 542 B1. The capping layer therein is formed from a material that resists oxidation and corrosion, e.g. Ru, Zr, Rh, Pd. The intermediate layer serves as a barrier layer which consists of B₄C or Mo and which is intended to prevent the material of the capping layer from diffusing into the topmost ply of the multilayer reflective coating.

The layers or plies of a reflective coating of an optical element for reflecting EUV radiation (EUV mirror) are subjected to harsh conditions during operation in an EUV lithography system, in particular in an EUV lithography apparatus: By way of example, the plies are impinged on by EUV radiation having a high radiation power. The EUV radiation also has the effect that some of the EUV mirrors heat up to high temperatures of possibly several 100° C. The residual gases in a vacuum environment in which the EUV mirrors are generally operated (e.g. oxygen, nitrogen, hydrogen, water, and further residual gases customary in ultra-high vacuum) can also impair the plies of the reflective coating, particularly if said gases are converted into reactive species such as ions or radicals, for example into a hydrogen-containing plasma, by the action of the EUV radiation. The ventilation of the vacuum environment in a pause in operation and unwanted leaks that occur can also lead to damage to the plies of the reflective coating. In addition, the plies of the reflective coating can be contaminated or damaged by hydrocarbons arising during operation, by volatile hydrides, by drops of tin, etc.

EP 1 364 231 B1 and U.S. Pat. No. 6,664,554 B2 disclose providing a self-cleaning optical element in an EUV lithography system, said optical element having a catalytic capping layer composed of Ru or Ru, Rh, Pd, Ir, Pt, Au for protecting a reflective coating against oxidation. A metallic layer composed of Cr, Mo or Ti can be introduced between the capping layer and the surface of the mirror.

EP 1 522 895 B1 has disclosed a method and an apparatus in which at least one mirror is provided with a dynamic protective layer in order to protect the mirror against etching with ions. The method comprises feeding a gaseous substance (as necessary) into a chamber containing the at least one mirror. The gas is typically a gaseous hydrocarbon (C_{X}H_{Y}). The protective effect of the carbon layer deposited in this way is limited, however, and the feeding and also the monitoring of the mirror necessitate a high outlay.

Further capping layers that are formed or can be formed from a plurality of plies are described in EP 1 065 568 B1, in DE 102012202850 A1, in JP2006080478 and in JP4352977 B2.

One of a plurality of possible damage patterns on a reflective optical element comprises layer cracks or holes in the capping layer, which have the effect that oxygen or other gases from the environment can reach the plies of the reflective coating. The materials of the plies oxidize or react with the gas in some other way, which can result in considerable losses in respect of the reflectivity of the EUV mirror.

### SUMMARY

It is an object of the invention to provide an optical element, an EUV lithography system and a method in which the damage to the reflective coating particularly as a result of oxidation is reduced.

According to one formulation, this object is achieved with an optical element of the type mentioned in the introduction in which the intermediate layer comprises at least one reactive material which, together with an activating gas penetrating through a gap in the capping layer, forms a reaction product sealing the gap.

The gap in the capping layer is generally a crack or a hole. The crack or the hole may be produced for example by the degradation mechanisms described further above. Sealing the gap is understood to mean that the further diffusion or penetration of the activating gas into the reflective coating is prevented or at least very greatly reduced.

The invention thus proposes using the activating gas penetrating through the gap to close or seal the gap before the activating gas reaches the underlying reflective coating and can damage the latter. The activating gas, which is actually damaging, is thus used to repair the capping layer by sealing the gap. For this purpose, it is not absolutely necessary for the reaction product to completely fill the gap in the capping layer, rather it is sufficient if the intermediate layer prevents the diffusion of the activating gas into the reflective coating in the region in which the gap occurs in the capping layer. The capping layer, to put it more precisely the combination of the capping layer and the intermediate layer, enables self-healing or repair of the optical element at any time, without the dynamic deposition of a protective layer being required for this purpose. Both the capping layer and the intermediate layer can be formed from or consist of a single ply or a plurality of plies.

In one embodiment, the reactive material is selected from the group comprising: borides, silicides and carbides. Metal borides, specifically vanadium boride (VB), has proved to be a suitable reactive material which, with oxygen as activating gas, forms two volatile or viscous oxides (e.g. V₂O₅ and B₂O₃). Particularly if the activating gas is present in the form of a plasma, as is generally the case for an EUV lithography system on account of the interaction with the EUV radiation, the oxidation can proceed at comparatively low temperatures of less than 100° C. Examples of such low-temperature plasma oxidation are described in the article “Scaling Requires Continuous Innovation in Thermal Processing: Low-Temperature Plasma Oxidation”, W. Lerch et al., ECS Trans. 2012, vol. 45, issue 6, pages 151-161 or in the article “Oxidation Kinetics of a Silicon Surface in a Plasma of Oxygen with Inert Gases”, A. Kh. Antonenko et al., Optoelectronics, Instrumentation and Data Processing, October 2011, vol. 47, issue 5, pages 459-464, which are incorporated by reference in their entirety in the content of this application.

In one embodiment, the activating gas is selected from the group comprising: oxygen, nitrogen, hydrogen and combinations thereof, for example water. For the purposes of this application, the activating gas is understood to mean not only the molecular form of the gas, but also ions and/or radicals of the gas, such as occur during operation of the optical element in an EUV lithography system generally as a result of the influence of the EUV radiation, which leads to plasma formation. The activating gas in the form of oxygen, hydrogen, water or nitrogen is generally present anyway in the residual gas atmosphere in the environment of the reflective optical element operated under vacuum conditions, i.e. it is not necessary for the activating gas to be additionally fed to the EUV lithography system from outside.

In a further embodiment, the intermediate layer has at least one ply composed of a (silicate) glass material, preferably composed of an aluminosilicate glass or composed of a borosilicate glass. The intermediate layer can consist of the ply composed of the glass material, but can also be formed from two or more plies. Plies composed of glass material are generally particularly smooth, cf. the article “Metal supported aluminosilicate ultra-thin films as a versatile tool for studying surface chemistry of zeolites”, S. Shaikhutdinov and H.-J. Freund, ChemPhysChem, vol. 14, pages 71-77 (2012), and can therefore improve reflection. Glass materials in the form of aluminosilicate glasses can form porous structures in the form of zeolites, into which the activating gas, e.g. in the form of oxygen, can easily penetrate in order to form the reaction product. As described in the article, thin plies or layers composed of silicate glasses which comprise metals other than Al, for example Ti, Fe, etc., can also form a porous structure that fosters the penetration of gases and thus repair.

In one development, the ply composed of the glass material contains at least one material selected from the group comprising: Al, Ti, Si, Ba, V, B, O, N, Zr, Sc, Mn, Ge, Pd, Cr. As has been described further above, the glass material can form a silicate glass in the form of an aluminosilicate glass or a borosilicate glass. Such glasses can also comprise other constituents, for example Ba. In particular, particles, e.g. composed of B or V, can be embedded into the glass material or into the glass matrix, as is described in greater detail further below. The silicate glass material or the composite glass can also comprise constituents which are not included in the above enumeration.

In a further development, the reactive material is introduced into the glass material, preferably in the form of nanoparticles. For the purposes of this application, nanoparticles are understood to mean particles whose average particle size or whose average diameter is less than 10 nm. In this case, the glass material can be for example a boron composite glass in which the reactive material is formed by boron particles embedded into the glass matrix. Such a self-healing boron composite glass is described for example in the article “2D- and 3D Observation and Mechanism of Self-Healing in Glass-Boron Composites”, S. Castanie et al., J. Am. Ceram. Soc. 99, 849-855 (2016), which is incorporated by reference in its entirety in the content of this application. The boron composite glass is produced by boron particles with a particle size of less than 5 μm being admixed with a glass powder which, in addition to SiO₂, also contains Al₂O₃, CaO and BaO.

As described in the article, a crack in a ply composed of such a glass material can self-heal by virtue of the boron particles reacting with oxygen as activating gas to form molten B₂O₃, which in turn reacts with the glass matrix to form borosilicate compounds, which, just like the molten B₂O₃, contribute to closing the crack. Glass composite materials comprising particles other than boron particles can also be used as glass materials for the ply of the intermediate layer. It is advantageous for the self-healing function here if the particles forming the reactive material form a highly viscous or volatile compound with the activating gas, for example with oxygen, as is the case e.g. for vanadium particles. Vanadium boride particles, Zn particles (forming ZnO), Bi particles (forming BiOₓ), Sc, Mn, Ge, Pd and/or Cr particles can also be used for this purpose. It is particularly advantageous if the reaction product establishes bridges or bonds in the glass matrix.

In a further embodiment, the reactive material is introduced into at least one further ply of the intermediate layer or the at least one further ply consists of the reactive material. In this case, the intermediate layer has at least two plies. In the case of an intermediate layer having two plies, the further ply with the reactive material preferably forms the lower ply facing the reflective coating. The intermediate layer can in particular also have a plurality of alternating plies composed of the glass material and composed of the reactive material.

The reactive material of the further ply can be for example vanadium boride (VB), which enables the self-healing of the glass material, cf. the article “Self-Healing Glassy Thin Coating for High-Temperature Applications”, S. Castanie et al., ACS Appl. Mater. Interfaces (2016), 8, 4208-4215, which is incorporated by reference in its entirety in the content of this application. During self-healing, the VB material of the further ply reacts with oxygen to form VOₓ and BOₓ, which are highly viscous. These reaction products can therefore cross into the ply composed of the glass material and react with the glass material in order to seal the crack or the gap. In the article cited, the glass material is an oxidic glass consisting of BaO, SiO₂, Al₂O₃ and CaO, but it is also possible to seal (silicate) glass materials having a different composition in the manner described further above.

In a further embodiment, the intermediate layer has a thickness of between 0.2 nm and 10 nm. In order to prevent the reflectivity of the optical element from decreasing too much as a result of the self-healing intermediate layer, the thickness of the intermediate layer must be chosen so as not to be too large. As is explained in the articles described further above, it is possible to produce plies composed of the glass material or composed of the reactive material with comparatively small layer thicknesses of significantly less than 50 nm. The ply composed of the glass material can optionally have just a few monolayers, i.e. an ultra-thin ply is involved.

In a further embodiment, the intermediate layer and/or the capping layer are/is applied by a method selected from the group comprising: laser beam evaporation (“pulsed laser deposition”, PLD), atomic layer deposition (ALD), magnetron sputtering and electron beam evaporation. In addition to laser beam evaporation, which is used for the deposition in the articles described above, in particular the other methods mentioned for depositing thin layers or plies are also suitable for depositing or producing the capping layer and/or the intermediate layer. Atomic layer deposition, in particular, enables very thin plies to be deposited.

In a further embodiment, the capping layer comprises at least one metallic material, an oxide or a nitride. These materials generally enable sufficient protection of the reflective coating against oxidation and other negative influences in conjunction with comparatively small layer thicknesses.

In a further embodiment, the material of the capping layer is selected from the group comprising: Ru, Rh, Pd, Ir, Ta, AlOₓ, HfOₓ, ZrOₓ, TaOₓ, TiOₓ, NbOₓ, WOₓ, CrOₓ, TiN, SiN, ZrN, YOₓ, LaOₓ, CeOₓ and combinations thereof. The materials enumerated have proved to be advantageous for the production of the capping layer. Like the intermediate layer, the capping layer, too, can be formed from one ply or from two or more plies composed of different materials.

In a further embodiment, the capping layer has a thickness of between 0.5 nm and 10 nm. As has been described further above in connection with the intermediate layer, the thickness of the capping layer should be chosen so as not to be too large in order to avoid an excessive loss in respect of the reflectivity of the optical element during passage through the capping layer. The thickness of the capping layer should be chosen so as not to be too small in order that the capping layer can fulfill its protection function for the reflective coating.

In a further embodiment, the reflective coating forms a multilayer coating for reflecting EUV radiation incident on the reflective optical element with normal incidence, wherein the multilayer coating has alternating plies composed of a first material and a second material having different refractive indices. Normal incidence of EUV radiation is typically understood to mean incidence of EUV radiation at an angle of incidence of typically less than approximately 45° with respect to the surface normal to the surface of the reflective optical element. The reflective multilayer coating is typically optimized for the reflection of EUV radiation at a predefined wavelength, which generally corresponds to the used wavelength of the EUV lithography system in which the optical element is used.

If EUV radiation at a used wavelength in the region of approximately 13.5 nm is intended to be reflected at the optical element, then the individual plies of the multilayer coating usually consist of molybdenum and silicon. Depending on the used wavelength employed, other material combinations such as e.g. molybdenum and beryllium, ruthenium and beryllium, or lanthanum and B₄C are likewise possible. In addition to the alternating plies, the reflective coating generally has intermediate layers for preventing diffusion (so-called barrier layers) and optionally further functional layers.

In an alternative embodiment, the reflective coating is configured for reflecting EUV radiation incident on the reflective optical element with grazing incidence. Grazing incidence of EUV radiation is typically understood to mean incidence of EUV radiation at an angle of incidence of typically more than approximately 60° with respect to the surface normal to the surface of the reflective optical element. A reflective coating configured for grazing incidence typically has a reflectivity maximum at at least one angle of incidence that is greater than 60°. Such a reflective coating is typically formed from at least one material which has a low refractive index and low absorption for the EUV radiation incident with grazing incidence. In this case, the reflective coating can contain a metallic material or can be formed from a metallic material, for example composed of Mo, Ru or Nb.

A further aspect of the invention relates to an EUV lithography system comprising: at least one optical element as described further above. The EUV lithography system can be an EUV lithography apparatus for exposing a wafer, or can be some other optical arrangement that uses EUV radiation, for example an EUV inspection system, for example for inspecting masks, wafers or the like that are used in EUV lithography. The optical element can be for example an EUV mirror of a projection system or of an illumination system, for example a collector mirror.

A further aspect of the invention relates to a method for sealing a gap in a capping layer of an optical element embodied as described further above, comprising: forming the reaction product with the activating gas penetrating through the gap in the capping layer, said reaction product sealing the gap.

Further features and advantages of the invention are evident from the following description of exemplary embodiments of the invention, with reference to the figures of the drawing showing details essential to the invention, and from the claims. The individual features can each be realized individually by themselves or as a plurality in any desired combination in one variant of the invention.

### BRIEF DESCRIPTION OF THE DRAWINGS

Exemplary embodiments are illustrated in the schematic drawing and are explained in the following description. In the figures:

FIGS. 1A-1C show schematic illustrations of a conventional EUV mirror, comprising a reflective multilayer coating and a capping layer, both without (FIG. 1A) and with (FIG. 1B) a crack that exposes the multilayer coating to an oxidizing gas (FIG. 1C),

FIGS. 2A and 2B show schematic illustrations analogous to FIGS. 1A-C, in which a self-healing intermediate layer sealing the crack is arranged between the capping layer and the multilayer coating, before (FIG. 2A) and after (FIG. 2B) conversion into a reaction product,

FIGS. 3A and 3B show schematic illustrations analogous to FIGS. 2A and 2B respectively with a reflective coating in the form of a single ply, and

FIG. 4 shows a schematic illustration of an EUV lithography apparatus.

### DETAILED DESCRIPTION

In the following description of the drawings, identical reference signs are used for identical or functionally identical components.

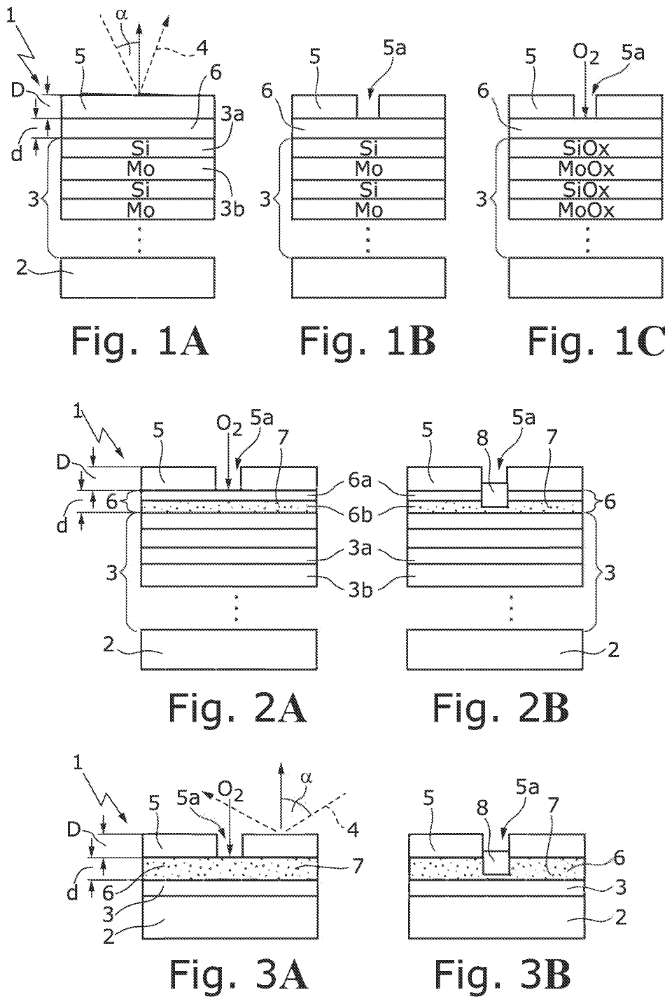

FIGS. 1A-C schematically show the construction of an optical element 1 comprising a substrate 2 and a reflective multilayer coating 3 for reflecting EUV radiation 4, said multilayer coating being applied to the substrate 2. A capping layer 5 forming an interface with the environment of the optical element 1 is applied to the reflective multilayer coating 3. In the example shown, the capping layer 5 is formed from Ru. An intermediate layer 6 is arranged between the capping layer 5 and the reflective multilayer coating 3, which intermediate layer, in the example shown, consists of C and serves as a barrier layer for preventing the Ru material from penetrating into the reflective multilayer coating 3.

The optical element 1 shown in FIGS. 1A-C is configured for reflecting EUV radiation 4 which is incident on the optical element 1 with normal incidence, i.e. at angles α of incidence of typically less than approximately 45° with respect to the surface normal. In this case, the reflective coating 3 is embodied as a multilayer coating and has a plurality of, e.g. more than fifty, alternating plies 3a, 3b formed from materials having different refractive indices.

In the example shown, in which the EUV radiation 4 has a used wavelength of 13.5 nm, the materials are silicon and molybdenum (see FIG. 1A). Depending on the used wavelength employed, other material combinations such as e.g. molybdenum and beryllium, ruthenium and beryllium, or lanthanum and B₄C are likewise possible. The substrate 2 is generally formed from a so-called zero expansion material having a very low coefficient of thermal expansion, for example composed of Zerodur® or composed of titanium-doped quartz glass (ULE®).

During operation of the optical element 1 in an EUV lithography apparatus, damage to the capping layer 5 can occur for various reasons, said damage resulting in the occurrence of a gap 5a in the capping layer 5. As can be discerned in FIG. 1B, the gap 5a extends over the entire thickness D of the capping layer 5 as far as the intermediate layer 6. The gap 5a illustrated in FIG. 1B can be a crack or a hole, for example. Through the gap 5a gases, for example oxygen O₂, from the environment can pass through the capping layer 5 to the intermediate layer 6 and diffuse through the latter into the reflective coating 3. In the reflective coating 3 the oxygen can oxidize the materials of the alternating plies 3a, 3b. In the example shown, the Si of the first plies 3a is at least partly oxidized to Si_{Ox} and the Mo of the second plies 3b is at least partly oxidized to MoOₓ, as is illustrated in FIG. 1C. The oxidation of the materials of the plies 3a, 3b alters the optical properties thereof, in particular the refractive index thereof, which has the effect that the reflectivity of the optical element 1 for the EUV radiation 4 decreases significantly.

In order to prevent such damage of the reflective coating 3 as a result of oxidation or to counteract the latter, the optical element 1 shown in FIGS. 2A,B has a self-healing intermediate layer 6, which seals the gap 5a or the crack, such that the oxygen O₂ penetrating through the capping layer 5 cannot diffuse as far as the reflective coating 3. In order to achieve this, in the example shown in FIGS. 2A,B, the intermediate layer 6 has a first, upper ply 6a composed of a glass material or a composite glass, composed of, in particular, aluminosilicate glass, and a second, lower ply 6b composed of vanadium boride (VB).

As has been described further above in association with FIGS. 1A-C, the oxygen O₂ in the form of a plasma passes through the gap 5a in the capping layer 5 and firstly impinges on the upper ply 6a of the intermediate layer 6. The upper ply 6a is formed from an aluminosilicate glass that has a zeolite structure and is porous. Such a ply 6a composed of aluminosilicate glass can be produced for example in the manner described in the article by S. Shaikhutdinov and H-J. Freund cited in the introduction. The layer thickness of the upper ply 6a is typically very small and can be for example less than approximately 10 nm or optionally 1 nm or less. In particular, the upper ply 6a can be formed only by one monolayer or optionally by a few monolayers of the aluminosilicate glass. Instead of an aluminosilicate, the upper ply 6a can also be formed from a silicate glass material in which Al is replaced by another metallic material, for example by Ti, Zr, etc.

The oxygen O₂ that has passed through the upper ply 6a and is present in the form of an O₂ plasma impinges on the lower ply 6b or diffuses into the latter. The O₂ plasma serves as activating gas for the vanadium boride material of the lower ply 6b, which constitutes a chemically reactive material 7 and is oxidized to VOₓ and BOₓ by the O₂ plasma at a comparatively low temperature of less than approximately 100° C. VOₓ and BOₓ are liquid or volatile reaction products 8 which penetrate from the lower ply 6b into the upper ply 6a and possibly partly further into the gap 5a and seal or close the latter. In this case, the reaction products 8 additionally react with the glass matrix of the upper ply 6a, such that the latter loses its porous structure and seals the gap 5a in the manner of a plug.

As has been described further above, it is possible to deposit or apply the upper ply 6a with a very small thickness. The same applies to the lower ply 6b composed of vanadium boride. The intermediate layer 6 can therefore have overall a very small thickness d that is between approximately 0.2 nm and approximately 10 nm. In this way it is ensured that the reflectivity of the optical element 1 is only slightly reduced by the presence of the intermediate layer 6.

The capping layer 5, too, has a thickness D that is between 0.5 nm and 10 nm in the example shown, in order to prevent the reflectivity of the optical element 1 from being excessively reduced by the presence of the capping layer 5. Besides the thickness D of the capping layer 5, the decrease in reflectivity is also dependent on the material of the capping layer 5. The capping layer 5 can comprise a metallic material, an oxide or a nitride, for example. In addition or as an alternative to the Ru described above, the material of the capping layer 5 can be selected from the group comprising: Rh, Pd, Ir, Ta, AlOₓ, HfOₓ, ZrOₓ, TaOₓ, TiOₓ, NbOₓ, WOₓ, CrOₓ, TiN, SiN, ZrN, YOₓ, LaOₓ, CeOₓ and combinations thereof. In a departure from the illustration in FIGS. 1A-C and in FIGS. 2A,B, the capping layer 5 can comprise two or more plies.

Instead of an optical element 1 having a self-healing intermediate layer 6 comprising two plies 6a, 6b, it is also possible to use a self-healing intermediate layer 6 which comprises only a single ply or which consists of the single ply, as is described below with reference to FIGS. 3A,B. The intermediate layer 6 shown in FIGS. 3A,B consists of a glass material in the form of a borosilicate glass or a silicate glass containing boron particles. The boron particles have a diameter of typically less than approximately 10 nm and are embedded into the glass matrix. Besides SiO₂, the glass material comprises further constituents, specifically Al₂O₃, CaO and BaO. The glass material of the intermediate layer 6 can correspond in particular to the composition described in the article in J. Am. Ceram. Soc. 99, 849-855 (2016) cited in the introduction. The glass material can additionally or alternatively also comprise other materials, for example Ti, N, Zr and/or V, B (see below).

The boron particles 7 form a reactive material which reacts with oxygen O₂ as activating gas (cf. FIG. 3A) and in this case forms liquid boron oxide (B₂O₃) as reaction product 8, said boron oxide sealing the gap 5a in the capping layer 5 (cf. FIG. 3B) by formation of bridges in the glass material and partly in the gap 5a, which limit or prevent the diffusion of oxygen O₂ into the reflective coating 3.

In contrast to the optical element 1 illustrated in FIGS. 2A,B, the optical element 1 illustrated in FIGS. 3A,B is designed for reflecting EUV radiation 4 incident with grazing incidence, i.e. for EUV radiation 4 which impinges on the optical element 1 at angles α of incidence of more than approximately 60° with respect to the surface normal. For this purpose, the reflective coating 3 comprises a single ply composed of ruthenium. In contrast to the illustration in FIGS. 3A,B, the reflective coating 3 can comprise two or more plies. Instead of ruthenium, the ply (plies) of the reflective coating 3 can also contain other materials or consist of other materials, e.g. composed of Mo or Nb. The substrate 2 of the optical element 1 illustrated in FIGS. 3A,B is formed from a ceramic material, for example composed of aluminum oxide (Al₂O₃) or composed of silicon carbide (SiC).

As an alternative to the examples described further above, the activating gas can be hydrogen or nitrogen or combinations thereof which, together with a suitable reactive material, form a reaction product which seals the gap 5a in the capping layer 5 and in this way prevents as completely as possible the diffusion of the active gas into the underlying reflective coating 3. The reactive material 7 can in principle be borides, silicides and carbides, for example the vanadium boride described further above. Boron or boron particles, vanadium or vanadium particles and optionally other types of particles can also serve as reactive material 7.

In the examples described further above, both the intermediate layer 6 and the capping layer 5 were applied by laser beam evaporation. However, it is also possible for the capping layer 5 and in particular the intermediate layer 6 to be applied to the substrate 2 or to the respective underlying ply or layer by some other coating method, for example by atomic layer deposition, magnetron sputtering or electron beam evaporation. Besides laser beam evaporation, atomic layer deposition, in particular, makes it possible to deposit very thin plies with a thickness of a few monolayers.

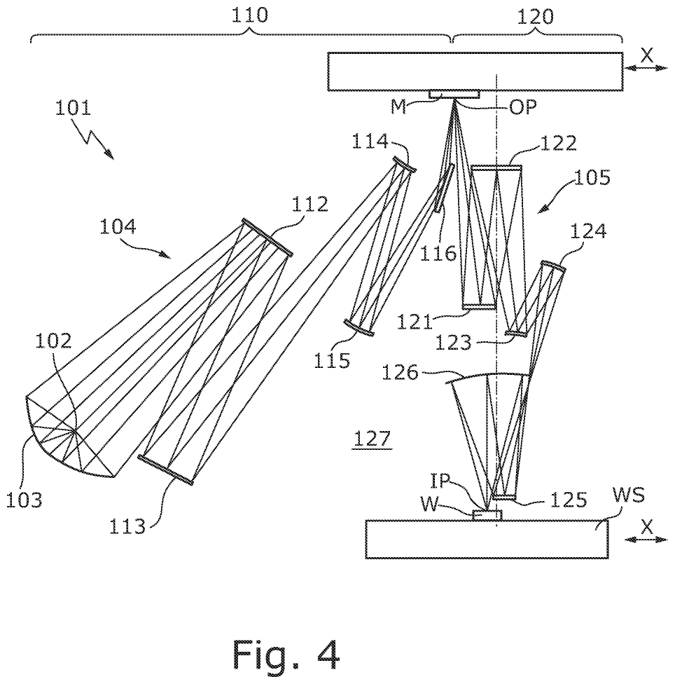

The optical elements 1 illustrated in FIGS. 2A,B and in FIGS. 3A,B can be used in an EUV lithography system in the form of an EUV lithography apparatus 101, as is illustrated schematically below in the form of a so-called wafer scanner in FIG. 4.

The EUV lithography apparatus 101 comprises an EUV light source 102 for generating EUV radiation, which has a high energy density in the EUV wavelength range below 50 nanometers, in particular between approximately 5 nanometers and approximately 15 nanometers. The EUV light source 102 can be embodied, for example, in the form of a plasma light source for generating a laser-induced plasma. The EUV lithography apparatus 101 shown in FIG. 4 is designed for an operating wavelength of the EUV radiation of 13.5 nm, for which the optical elements 1 illustrated in FIGS. 2A,B and in FIGS. 3A,B are also designed. However, it is also possible for the EUV lithography apparatus 101 to be configured for a different operating wavelength in the EUV wavelength range, such as 6.8 nm, for example.

The EUV lithography apparatus 101 furthermore comprises a collector mirror 103 in order to focus the EUV radiation of the EUV light source 102 to form an illumination beam 104 and to increase the energy density further in this way. The illumination beam 104 serves for the illumination of a structured object M with an illumination system 110, which in the present example has five reflective optical elements 112 to 116 (mirrors).

The structured object M can be for example a reflective photomask, which has reflective and non-reflective, or at least less reflective, regions for producing at least one structure on the object M. Alternatively, the structured object M can be a plurality of micro-mirrors, which are arranged in a one-dimensional or multi-dimensional arrangement and which are optionally movable about at least one axis, in order to set the angle of incidence of the EUV radiation on the respective mirror.

The structured object M reflects part of the illumination beam 104 and shapes a projection beam path 105, which carries the information about the structure of the structured object M and is radiated into a projection lens 120, which generates a projected image of the structured object M or of a respective partial region thereof on a substrate W. The substrate W, for example a wafer, comprises a semiconductor material, for example silicon, and is disposed on a mounting, which is also referred to as a wafer stage WS.

In the present example, the projection lens 120 has six reflective optical elements 121 to 126 (mirrors) in order to generate an image of the structure that is present at the structured object M on the wafer W. The number of mirrors in a projection lens 120 typically lies between four and eight; however, only two mirrors can also be used, if appropriate.

The reflective optical elements 103, 112 to 116 of the illumination system 110 and the reflective optical elements 121 to 126 of the projection lens 120 are arranged in a vacuum environment 127 during the operation of the EUV lithography apparatus 101. A residual gas atmosphere containing, inter alia, oxygen, hydrogen and nitrogen and water is formed in the vacuum environment 127.

The optical element 1 illustrated in FIGS. 2A,B can be one of the optical elements 103, 112 to 115 of the illumination system 110 or one of the reflective optical elements 121 to 126 of the projection lens 120 which are designed for normal incidence of the EUV radiation 4. The optical element 1 shown in FIGS. 3A,B and designed for grazing incidence of the EUV radiation 4 can be the last optical element 116 of the illumination system 110. In contrast to the illustration in FIG. 4, further reflective optical elements 103, 112 to 115 of the illumination system 110 and/or reflective optical elements 121 to 126 of the projection system 120 can be configured for EUV radiation 4 incident with grazing incidence.

What is claimed is:

1. An optical element for reflecting extreme ultraviolet (EUV) radiation, comprising:
a substrate,
a reflective coating applied to the substrate and configured to reflect the EUV radiation,
a capping layer applied to the reflective coating and configured to protect the reflective coating, and
an intermediate layer arranged between the reflective coating and the capping layer, wherein the intermediate layer comprises at least one reactive material which, together with an activating gas penetrating through a gap in the capping layer, forms at least one reaction product sealing the gap, and wherein the intermediate layer has at least one ply composed of a glass material.

2. The optical element as claimed in claim 1, wherein the reactive material is selected from the group consisting essentially of: borides, silicides and carbides.

3. The optical element as claimed in claim 1, wherein the activating gas is selected from the group consisting essentially of: oxygen (O₂), nitrogen, hydrogen and combinations thereof.

4. The optical element as claimed in claim 3, wherein the activating gas is water.

5. The optical element as claimed in claim 1, wherein the ply is formed from an aluminosilicate glass or from a borosilicate glass.

6. The optical arrangement as claimed in claim 1, wherein the ply contains at least one material selected from the group consisting essentially of: Al, Ti, Si, Ba, V, B, O, N, Zr, Sc, Mn, Ge, Pd, Cr.

7. The optical element as claimed in claim 1, wherein the reactive material is introduced into the glass material.

8. The optical element as claimed in claim 7, wherein the reactive material is introduced into the glass material as nanoparticles.

9. The optical element as claimed in claim 1, wherein the reactive material is introduced into at least one further ply of the intermediate layer.

10. The optical element as claimed in claim 1, wherein the intermediate layer has a thickness of between 0.2 nm and 10 nm.

11. The optical element as claimed in claim 1, wherein the intermediate layer and/or the capping layer are/is applied by a method selected from the group consisting essentially of: laser beam evaporation, atomic layer deposition, magnetron sputtering and electron beam evaporation.

12. The optical element as claimed in claim 1, wherein the capping layer comprises at least one metallic material, an oxide or a nitride.

13. The optical element as claimed in claim 1, wherein the material of the capping layer is selected from the group consisting essentially of: Ru, Rh, Pd, Ir, Ta, AlOₓ, HfOₓ, ZrOₓ, TaOₓ, TiOₓ, NbOₓ, WOₓ, CrOₓ, TiN, SiN, ZrN, YOₓ, LaOₓ, CeOₓ and combinations thereof.

14. The optical element as claimed in claim 1, wherein the capping layer has a thickness of between 0.5 nm and 10 nm.

15. The optical element as claimed in claim 1, wherein the reflective coating forms a multilayer coating for reflecting EUV radiation incident on the reflective optical element with normal incidence, wherein the multilayer coating has alternating plies composed of a first material and a second material having different refractive indices.

16. The optical element as claimed in claim 1, wherein the reflective coating is configured for reflecting EUV radiation incident on the reflective optical element with grazing incidence.

17. An EUV lithography system comprising:
at least one optical element as claimed in claim 1.

18. A method for sealing a gap in a capping layer of an optical element as claimed in claim 1, comprising:
forming the reaction product with the activating gas penetrating through the gap in the capping layer, and
sealing the gap with the formed reaction product.
